(19) United States
(12) Patent Application Publication
(10) Pub. No.: US 2026/0293258 A1
(43) Pub. Date: Sep. 24, 2026

(54) SEMICONDUCTOR DEVICE AND METHOD FOR MANUFACTURING THE SAME

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Hirofumi KAWAI, Nonoichi Ishikawa (JP)

(21) Appl. No.: 19/297,730

(22) Filed: Aug. 12, 2025

(30) Foreign Application Priority Data
Mar. 19, 2025 (JP) 2025-045772

(51) Int. Cl. H10D 64/00; H10D 30/66; H10D 64/01

(52) U.S. Cl. CPC H10D 64/117; H10D 30/665; H10D 30/668; H10D 64/01

(57) ABSTRACT

A semiconductor device according to an embodiment includes a first semiconductor region, first and second insulating regions, first to fourth high-concentration layers, and first and second contact pairs. In the first semiconductor region, an impurity concentration decreases from a lower surface toward an upper surface. The first and second insulating regions are provided from the upper surface toward the lower surface, and the lower ends are positioned at heights at which the impurity concentrations of the first semiconductor region are a first concentration and a second concentration. The first contact pair includes first and second contact portions electrically connected to the first and second high-concentration layers that sandwich the first insulating region in a third direction. The second contact pair includes third and fourth contact portions that are respectively electrically connected to the third and fourth high-concentration layers that sandwich the second insulating region in the third direction.

### CROSS-REFERENCE TO RELATED APPLICATIONS

This application is based upon and claims the benefit of priority from the prior Japanese Patent Application No. 2025-045772, filed on Mar. 19, 2025; the entire contents of which are incorporated herein by reference.

### FIELD

Embodiments described herein relate generally to a semiconductor device and a method for manufacturing the same.

### BACKGROUND

A semiconductor device having a semiconductor region in which a plurality of epitaxial growth layers are stacked is known. In such a semiconductor device, it is not easy to inspect the quality of the epitaxial growth layer in some cases.

### BRIEF DESCRIPTION OF THE DRAWINGS

FIG. 1 is a plan view of a semiconductor device according to a first embodiment.

FIG. 2 is a cross-sectional view of a semiconductor device according to a first embodiment.

FIG. 3 is a graph illustrating a relationship between a resistance value and an electric field intensity of a first semiconductor region in the semiconductor device according to the first embodiment.

FIG. 4 is a schematic cross-sectional view illustrating an operation example of the semiconductor device according to the first embodiment.

FIG. 5A is a cross-sectional view illustrating an example of a manufacturing process of the semiconductor device according to the first embodiment.

FIG. 5B is a cross-sectional view illustrating an example of the manufacturing process of the semiconductor device according to the first embodiment, subsequent to FIG. 5A.

FIG. 5C is a cross-sectional view illustrating an example of the manufacturing process of the semiconductor device according to the first embodiment, subsequent to FIG. 5B.

FIG. 6 is a cross-sectional view of an operation example of the semiconductor device according to a modification of the first embodiment.

FIG. 7 is a cross-sectional view of a semiconductor device according to a second embodiment.

FIG. 8A is a cross-sectional view illustrating an example of a manufacturing process of the semiconductor device according to the second embodiment.

FIG. 8B is a cross-sectional view illustrating an example of the manufacturing process of the semiconductor device according to the second embodiment, subsequent to FIG. 8A.

FIG. 8C is a cross-sectional view illustrating an example of the manufacturing process of the semiconductor device according to the second embodiment, subsequent to FIG. 8B.

FIG. 8D is a cross-sectional view illustrating an example of the manufacturing process of the semiconductor device according to the second embodiment, subsequent to FIG. 8C.

FIG. 8E is a cross-sectional view illustrating an example of the manufacturing process of the semiconductor device according to the second embodiment, subsequent to FIG. 8D.

FIG. 9 is a cross-sectional view of a semiconductor device according to a third embodiment.

### DETAILED DESCRIPTION

A semiconductor device according to an embodiment includes a first semiconductor region, a first insulating region, a second insulating region, first and second high-concentration layers, third and fourth high-concentration layers, a first contact pair, and a second contact pair. In the first semiconductor region, an impurity concentration of a first or second conductivity type decreases from a lower surface toward an upper surface along a first direction that is a thickness direction. The first insulating region is provided from the upper surface of the first semiconductor region toward the lower surface of the first semiconductor region, has a lower end positioned at a height at which the impurity concentration of the first semiconductor region is a first concentration, and extends in a second direction orthogonal to the first direction. The second insulating region is provided from the upper surface of the first semiconductor region toward the lower surface of the first semiconductor region, has the lower end positioned at a height at which the impurity concentration of the first semiconductor region is a second concentration lower than the first concentration, and extends in the second direction. The first and second high-concentration layers are provided on the upper surface of the first semiconductor region and sandwich the first insulating region in a third direction orthogonal to the first direction and the second direction. The third and fourth high-concentration layers are provided on the upper surface of the first semiconductor region and sandwich the second insulating region in the third direction. The first contact pair includes a first contact portion electrically connected to the first high-concentration layer and a second contact portion electrically connected to the second high-concentration layer. The second contact pair includes a third contact portion electrically connected to the third high-concentration layer and a fourth contact portion electrically connected to the fourth high-concentration layer.

Hereinafter, embodiments according to the present invention are described with reference to the drawings. The embodiments do not limit the present invention. The drawings are schematic or conceptual, and the ratio of each portion and the like are not necessarily the same as actual ones. In the specification and the drawings, elements similar to those described above with respect to the previously described drawings are denoted by the same reference numerals, and the detailed description thereof is appropriately omitted.

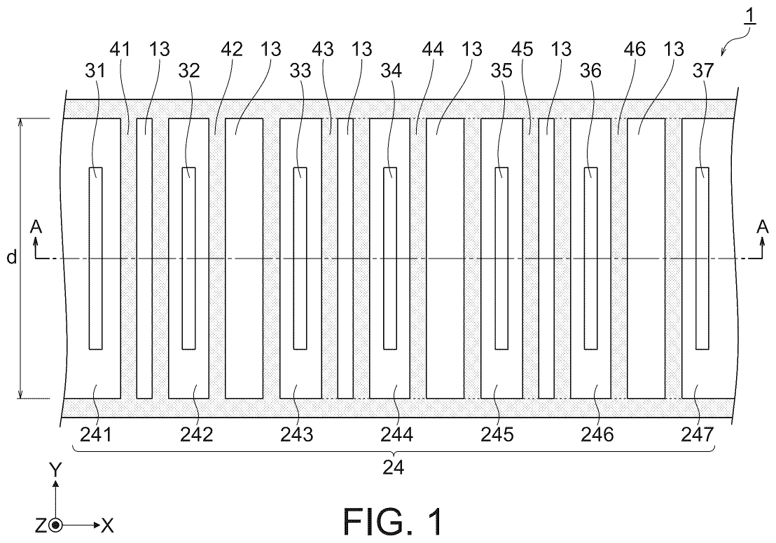

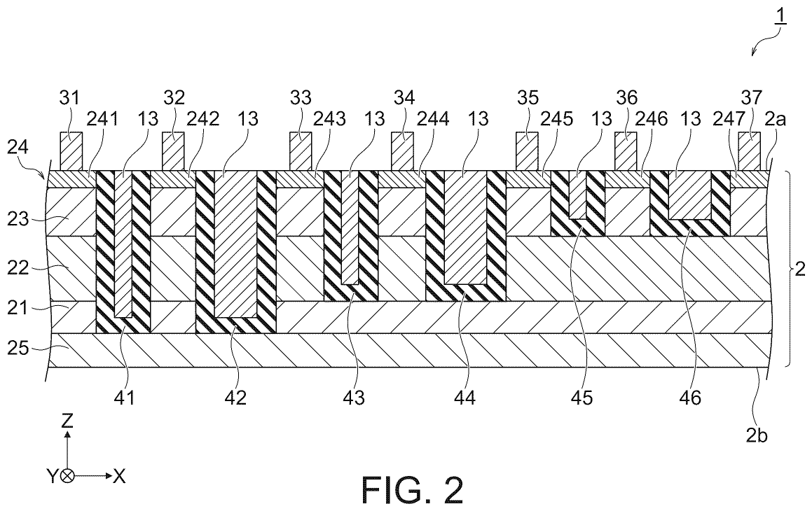

In addition, for convenience of description, an XYZ orthogonal coordinate system is adopted as illustrated in FIGS. 1 and 2, and the like. A Z-axis direction is a stacking direction (thickness direction) of the semiconductor device. In addition, in the Z-axis direction, a source electrode side is also referred to as “upper”, and a drain electrode side is also referred to as “lower”. However, this expression is for convenience and independent of the direction of gravity. The Z-axis direction is a first direction in the claims. A Y-axis direction is a second direction in the claims. An X-axis direction is a third direction in the claims.

In addition, in the following description, notations of n⁺, n, and n⁻, and p⁺, p, and p⁻ may be used to represent the relative level of impurity concentration in each conductivity type. That is, n⁺ indicates that an n-type impurity concentration is relatively higher than n, and n⁻ indicates that the n-type impurity concentration is relatively lower than n. In addition, p⁺ indicates that a p-type impurity concentration is relatively higher than p, and p⁻ indicates that the p-type impurity concentration is relatively lower than p. When both the p-type impurity and the n-type impurity are included in each region, these notations represent the relative level of the net impurity concentration after the impurities are compensated. The n type, n⁺ type, and n⁻ type are examples of a first conductivity type in the claims. The p type, p⁺type, and p⁻ type are examples of a second conductivity type in the claims. Note that in the following description, the n-type and the p-type may be reversed. That is, the first conductivity type may be the p type.

In addition, the impurity concentration of the semiconductor region can be measured, for example, by secondary ion mass spectrometry (SIMS). In addition, the relative level of the impurity concentration can also be determined, for example, from the level of a carrier concentration obtained by scanning capacitance microscopy (SCM).

In addition, a dimension such as the height or the width of the insulating region can be measured, for example, by analysis of a surface and/or a cross section by a transmission electron microscope (TEM), an energy dispersive X-ray spectroscopy (EDX), or a scanning electron microscope (SEM).

Note that terms such as “identical”, “same”, and “equal”, dimensions, values of physical characteristics, and the like, which specify shapes, geometric conditions, physical characteristics, and the degrees thereof, used in the present specification, are interpreted including a range in which similar functions can be expected, without being bound by a strict meaning.

### First Embodiment

A semiconductor device 1 according to a first embodiment is described with reference to FIGS. 1 and 2. FIG. 1 is a plan view of the semiconductor device 1 according to the first embodiment. FIG. 2 is a cross-sectional view of the semiconductor device 1 according to the first embodiment, the cross-sectional view which is taken along line A-A in FIG. 1.

As illustrated in FIGS. 1 and 2, the semiconductor device 1 according to the present embodiment includes a semiconductor layer 2 and contact portions 31 to 37.

As illustrated in FIG. 2, the semiconductor layer 2 includes an upper surface 2a and a lower surface 2b on a side opposite to the upper surface 2a. The semiconductor layer 2 includes, for example, a field plate electrode (FP electrode) 13, an epitaxial growth layer 21, an epitaxial growth layer 22, an epitaxial growth layer 23, a high-concentration layer 24, a substrate 25, an insulating region 41, an insulating region 42, an insulating region 43, an insulating region 44, an insulating region 45, and an insulating region 46.

The semiconductor layer 2 includes the substrate 25 that is a semiconductor substrate and the epitaxial growth layers 21 to 23 disposed thereon. In the present embodiment, the semiconductor layer 2 is silicon (Si). In this case, for example, arsenic (As), phosphorus (P), or antimony (Sb) is used as the n-type impurity, and for example, boron (B) is used as the p-type impurity. In the present embodiment, the epitaxial growth layers 21 to 23, the high-concentration layer 24, and substrate 25 are n-type semiconductor regions. Phosphorus is used as the n-type impurity of the epitaxial growth layers 21 to 23, and arsenic is used as the n-type impurity of the substrate 25. Note that the epitaxial growth layers 21 to 23, the high-concentration layer 24, and the substrate 25 may be p-type semiconductor regions. In addition, the semiconductor layer 2 may be made of a compound semiconductor such as silicon carbide (SiC) or gallium nitride (GaN).

The FP electrodes 13 are provided inside the insulating regions 41 to 46. By providing the FP electrode 13, when the semiconductor device 1 is in the off state, a depletion layer extends from the insulating regions 41 to 46 where the FP electrode 13 is disposed to the surrounding semiconductor region, for example, by a reverse voltage applied between a drain electrode and a source electrode (not illustrated). This depletion layer is connected to the depletion layer extending from the insulating regions 41 to 46 where the adjacent FP electrodes 13 are arranged, so that the withstand voltage of the semiconductor device 1 can be improved.

Note that, in the examples of FIGS. 1 and 2, the width (length in the X-axis direction) of the FP electrode 13 provided in the insulating regions 42, 44, and 46 is longer than the width of the FP electrode 13 provided in the insulating regions 41, 43, and 45. The present invention is not limited thereto, and the width of the FP electrodes 13 provided in the insulating regions 42, 44, and 46 may be the same as the width of the FP electrodes 13 provided in the insulating regions 41, 43, and 45. Alternatively, the FP electrodes 13 may not be provided inside the insulating regions 41 to 46.

The epitaxial growth layer 21 is provided on the substrate 25 and includes n-type or p-type impurities. In the present embodiment, the impurity concentration of the epitaxial growth layer 21 is the first concentration. The resistivity (specific resistance) of the epitaxial growth layer 21 is the first resistivity. The first resistivity is, for example, 0.03 Ω·cm. The epitaxial growth layer 21 is an example of a first epitaxial growth layer in the claims.

The epitaxial growth layer 22 is provided on the epitaxial growth layer 21 and includes impurities of the same conductivity type as the epitaxial growth layer 21. In the present embodiment, the impurity concentration of the epitaxial growth layer 22 is the second concentration. The second concentration is lower than the first concentration that is the impurity concentration of the epitaxial growth layer 21. Therefore, the resistivity of the epitaxial growth layer 22 is a second resistivity larger than the first resistivity that is the resistivity of the epitaxial growth layer 21. The second resistivity is, for example, 0.17 Ω·cm. The epitaxial growth layer 22 is an example of a second epitaxial growth layer in the claims.

The epitaxial growth layer 23 is provided on the epitaxial growth layer 22 and includes impurities of the same conductivity type as the epitaxial growth layers 21 and 22. In the present embodiment, the impurity concentration of the epitaxial growth layer 23 is the third concentration. The third concentration is lower than the second concentration that is the impurity concentration of the epitaxial growth layer 22. Therefore, the resistivity of the epitaxial growth layer 23 is a third resistivity larger than the second resistivity that is the resistivity of the epitaxial growth layer 22. The third resistivity is, for example, 0.6 Ω·cm. The epitaxial growth layer 23 is an example of a third epitaxial growth layer in the claims.

The high-concentration layer 24 is provided on the epitaxial growth layer 23. The high-concentration layer 24 includes impurities having the same conductivity type as that of the epitaxial growth layers 21 to 23. That is, the epitaxial growth layers 21 to 23, the high-concentration layer 24, and the substrate 25 have the same conductivity type. In other words, a region having a different conductivity type is not provided around the insulating regions 41 to 46 illustrated in FIG. 2. In the present embodiment, the high-concentration layer 24 is an n⁺-type semiconductor region, and the impurity concentration of the high-concentration layer 24 is higher than the impurity concentration of the epitaxial growth layer 23. The impurity concentration of the high-concentration layer 24 is, for example, 1×10¹⁸ cm⁻³ to 1×10²² cm⁻³. This makes it possible to ensure ohmic contact between the high-concentration layer 24 and the contact portions 31 to 37 described below.

As illustrated in FIGS. 1 and 2, the high-concentration layer 24 includes a high-concentration layer 241, a high-concentration layer 242, a high-concentration layer 243, a high-concentration layer 244, a high-concentration layer 245, a high-concentration layer 246, and a high-concentration layer 247. The high-concentration layers 241 to 247 are respectively electrically connected to the contact portions 31 to 37 described below.

The high-concentration layer 241 and the high-concentration layer 242 are provided so as to sandwich the insulating region 41 in the X-axis direction orthogonal to the Z-axis direction and the Y-axis direction. The high-concentration layer 241 and the high-concentration layer 242 are examples of ninth and tenth high-concentration layers in the claims.

The high-concentration layer 242 and the high-concentration layer 243 are provided so as to sandwich the insulating region 42 in the X-axis direction.

The high-concentration layer 243 and the high-concentration layer 244 are provided so as to sandwich the insulating region 43 in the X-axis direction. The high-concentration layer 243 and the high-concentration layer 244 are examples of first and second high-concentration layers in the claims.

The high-concentration layer 244 and the high-concentration layer 245 are provided so as to sandwich the insulating region 44 in the X-axis direction. The high-concentration layer 244 and the high-concentration layer 245 are examples of fifth and sixth high-concentration layers in the claims.

The high-concentration layer 245 and the high-concentration layer 246 are provided so as to sandwich the insulating region 45 in the X-axis direction. The high-concentration layer 245 and the high-concentration layer 246 are examples of third and fourth high-concentration layers in the claims.

The high-concentration layer 246 and the high-concentration layer 247 are provided so as to sandwich the insulating region 46 in the X-axis direction. The high-concentration layer 246 and the high-concentration layer 247 are examples of seventh and eighth high-concentration layers in the claims.

As illustrated in FIG. 1, the high-concentration layers 241 to 247 extend in the Y-axis direction orthogonal to the Z-axis direction. Note that the high-concentration layers 241 to 247 may extend by a predetermined length in the Y-axis direction. In this case, for example, the insulating region 41 and the insulating region 42 may be connected at the upper portion of the high-concentration layer 242 in FIG. 1.

Note that, in the following description, when the high-concentration layers 241 to 247 are not distinguished, the high-concentration layers 241 to 247 are collectively referred to as the high-concentration layer 24.

As illustrated in FIG. 2, the substrate 25 is positioned below the epitaxial growth layer 21. The substrate 25 includes impurities having the same conductivity type as that of the epitaxial growth layers 21 to 23. In the present embodiment, the impurity concentration of the substrate 25 is higher than the first concentration that is the impurity concentration of the epitaxial growth layer 21. Therefore, the resistivity of the substrate 25 is lower than the first resistivity which is the resistivity of the epitaxial growth layer 21. The resistivity of the substrate 25 is, for example, 1 mΩ·cm.

The epitaxial growth layer 21, the epitaxial growth layer 22, the epitaxial growth layer 23, and the substrate 25 configure a first semiconductor region in the claims. That is, in the epitaxial growth layer 21, the epitaxial growth layer 22, the epitaxial growth layer 23, and the substrate 25, which are the first semiconductor region, the n-type impurity concentration decreases from the lower surface of the first semiconductor region toward the upper surface of the first semiconductor region along the Z-axis direction that is the thickness direction of the semiconductor layer 2. Note that, in the example of FIG. 2, the lower surface of the first semiconductor region (the lower surface of the substrate 25) is positioned on the lower surface 2b of the semiconductor layer 2. Meanwhile, the upper surface of the first semiconductor region (the upper surface of the epitaxial growth layer 23) is in contact with the lower surface of the high-concentration layer 24. The upper surface of the high-concentration layer 24 is positioned on the upper surface 2a of the semiconductor layer 2.

Note that, in the present embodiment, the first semiconductor region has three layers of the epitaxial growth layers 21 to 23. The present invention is not limited thereto, and the first semiconductor region may have two or four or more epitaxial growth layers. When the first semiconductor region has a plurality of epitaxial growth layers, the epitaxial growth layers may have constant impurity concentrations, and the impurity concentration may gradually decrease from the lower surface to the upper surface of the first semiconductor region. Alternatively, the impurity concentration in the first semiconductor region may continuously decrease from the lower surface to the upper surface of the first semiconductor region. When the impurity concentration continuously decreases, the first semiconductor region may have one epitaxial growth layer in which the impurity concentration continuously decreases from the lower surface to the upper surface of the first semiconductor region.

Note that, FIG. 2 illustrates a boundary between the substrate 25 and the epitaxial growth layer 21, a boundary between the epitaxial growth layer 21 and the epitaxial growth layer 22, and a boundary between the epitaxial growth layer 22 and the epitaxial growth layer 23. However, in the actual semiconductor device 1, the impurity concentration of the substrate 25 and the epitaxial growth layers 21 to 23 may continuously change by performing the heat treatment. Therefore, these boundaries may be unclear.

All of the insulating regions 41 to 46 are provided from the upper surface of the first semiconductor region toward the lower surface of the first semiconductor region. The insulating regions 41 to 46 include, for example, silicon oxide or silicon nitride.

The lower end of the insulating region 41 is positioned at a height (position in the Z-axis direction) at which the impurity concentration of the first semiconductor region is higher than the first concentration. In the present embodiment, the lower end of the insulating region 41 is positioned at the same height as the boundary between the substrate 25 and the epitaxial growth layer 21. The insulating region 41 is an example of a fifth insulating region in the claims.

The lower end of the insulating region 42 is positioned at the same height as that of the insulating region 41. That is, the lower end of the insulating region 42 is positioned at a height at which the impurity concentration of the first semiconductor region is higher than the first concentration. In the present embodiment, the lower end of the insulating region 42 is positioned at the same height as the boundary between the substrate 25 and the epitaxial growth layer 21. In addition, the insulating region 42 is different in width from the insulating region 41.

The lower end of the insulating region 43 is positioned at a height (a first height) at which the impurity concentration of the first semiconductor region is the first concentration. In the present embodiment, the lower end of the insulating region 43 is positioned at the same height as the boundary between the epitaxial growth layer 21 and the epitaxial growth layer 22. The insulating region 43 is an example of a first insulating region in the claims.

The lower end of the insulating region 44 is positioned at the same height as that of the insulating region 43. That is, the lower end of the insulating region 44 is positioned at a height at which the impurity concentration of the first semiconductor region is the first concentration. In the present embodiment, the lower end of the insulating region 44 is positioned at the same height as the boundary between the epitaxial growth layer 21 and the epitaxial growth layer 22. In addition, the insulating region 44 is different in width from the insulating region 43. The insulating region 43 is an example of a third insulating region in the claims.

The lower end of the insulating region 45 is positioned at a height (a second height) at which the impurity concentration of the first semiconductor region is the second concentration. In the present embodiment, the lower end of the insulating region 45 is positioned at the same height as the boundary between the epitaxial growth layer 22 and the epitaxial growth layer 23. The insulating region 45 is an example of a second insulating region in the claims.

The lower end of the insulating region 46 is positioned at the same height as that of the insulating region 45. That is, the lower end of the insulating region 46 is positioned at a height at which the impurity concentration of the first semiconductor region is the second concentration. In the present embodiment, the lower end of the insulating region 46 is positioned at the same height as the boundary between the epitaxial growth layer 22 and the epitaxial growth layer 23. In addition, the insulating region 46 is different in width from the insulating region 45. The insulating region 46 is an example of a fourth insulating region in the claims.

As illustrated in FIG. 1, the insulating regions 41 to 46 extend in the Y-axis direction. In the present embodiment, the insulating regions 41 to 46 extend at least over a length d in the Y-axis direction. The length d is, for example, 10 μm. Note that, the length d may be longer or shorter than 10 μm as long as the path of the current can pass through the bottom of the insulating regions 41 to 46 in the Z-axis direction when the resistance value of the first semiconductor region is measured. As a result, the resistivity of the epitaxial growth layers 21 to 23 can be appropriately measured.

Also, in the present embodiment, as illustrated in FIG. 1, the insulating region 41 is further provided so as to sandwich both end portions of the insulating regions 41 to 46 in the Y-axis direction. That is, a portion of the insulating region 41 extending in the Y-axis direction and one end portions (upper end portions in FIG. 1) of the insulating regions 42 to 46 in the Y-axis direction are connected to the insulating region 41 extending in the X-axis direction. Similarly, a portion of the insulating region 41 extending in the Y-axis direction and the other end portions (lower end portions in FIG. 1) of the insulating regions 42 to 46 in the Y-axis direction are connected to the insulating region 41 extending in the X-axis direction. As a result, when the resistance value of the first semiconductor region is measured, it is possible to more reliably make the path of the current pass through the bottom portions of the insulating regions 41 to 46 in the Z-axis direction. Note that, instead of the insulating region 41, an insulating region in which the height of the lower end is different from that of the insulating region 41 may be provided so as to sandwich both ends of the insulating regions 41 to 46 in the Y-axis direction. For example, instead of the insulating region 41, any one of the insulating regions 43 to 46 may be provided so as to sandwich both ends of the insulating regions 41 to 46 in the Y-axis direction.

As illustrated in FIGS. 1 and 2, the contact portions 31 to 37 are provided on the upper surface 2a of the semiconductor layer 2 and are electrically connected to the high-concentration layers 241 to 247 on the upper surface 2a of the semiconductor layer 2, respectively. More specifically, the contact portion 31 is electrically connected to the high-concentration layer 241, the contact portion 32 is electrically connected to the high-concentration layer 242, the contact portion 33 is electrically connected to the high-concentration layer 243, the contact portion 34 is electrically connected to the high-concentration layer 244, the contact portion 35 is electrically connected to the high-concentration layer 245, the contact portion 36 is electrically connected to the high-concentration layer 246, and the contact portion 37 is electrically connected to the high-concentration layer 247. Note that the contact portions 31 to 37 may be electrically connected to a monitor pad or the like arranged on a dicing line of the semiconductor device 1.

In addition, the contact portion 31 and the contact portion 32 configure a contact pair for measuring the resistance of the first semiconductor region straddling over the insulating region 41 between the contact portion 31 and the contact portion 32. The contact portion 31 is an example of a ninth contact portion in the claims. The contact portion 32 is an example of a tenth contact portion in the claims. The contact pair configured by the contact portion 31 and the contact portion 32 is an example of a fifth contact pair in the claims.

The contact portion 32 and the contact portion 33 configure a contact pair for measuring the resistance of the first semiconductor region straddling over the insulating region 42 between the contact portion 32 and the contact portion 33.

The contact portion 33 and the contact portion 34 configure a contact pair for measuring the resistance of the first semiconductor region straddling over the insulating region 43 between the contact portion 33 and the contact portion 34. The contact portion 33 is an example of a first contact portion in the claims. The contact portion 34 is an example of a second contact portion in the claims. The contact pair configured by the contact portion 33 and the contact portion 34 is an example of a first contact pair in the claims.

The contact portion 34 and the contact portion 35 configure a contact pair for measuring the resistance of the first semiconductor region straddling over the insulating region 44 between the contact portion 34 and the contact portion 35. The contact portion 33 is an example of a fifth contact portion in the claims. The contact portion 34 is an example of a sixth contact portion in the claims. The contact pair configured by the contact portion 34 and the contact portion 35 is an example of a third contact pair in the claims.

The contact portion 35 and the contact portion 36 configure a contact pair for measuring the resistance of the first semiconductor region straddling over the insulating region 45 between the contact portion 35 and the contact portion 36. The contact portion 35 is an example of a third contact portion in the claims. The contact portion 36 is an example of a fourth contact portion in the claims. The contact pair configured by the contact portion 35 and the contact portion 36 is an example of a second contact pair in the claims.

The contact portion 36 and the contact portion 37 configure a contact pair for measuring the resistance of the first semiconductor region straddling over the insulating region 46 between the contact portion 36 and the contact portion 37. The contact portion 36 is an example of a seventh contact portion in the claims. The contact portion 37 is an example of an eighth contact portion in the claims. The contact pair configured by the contact portion 36 and the contact portion 37 is an example of a fourth contact pair in the claims.

Note that in the example of FIG. 2, one contact portion is electrically connected to one high-concentration layer. Not limited to this, with respect to the high-concentration layer 242 to the high-concentration layer 246, two contact portions may be electrically connected to one high-concentration layer, and these contact portions may configure mutually different contact pairs. For example, two contact portions 34 may be electrically connected to the high-concentration layer 244, one contact portion 34 and the contact portion 33 may configure one contact pair (first contact pair), and the other contact portion 34 and the contact portion 35 may configure another contact pair (third contact pair).

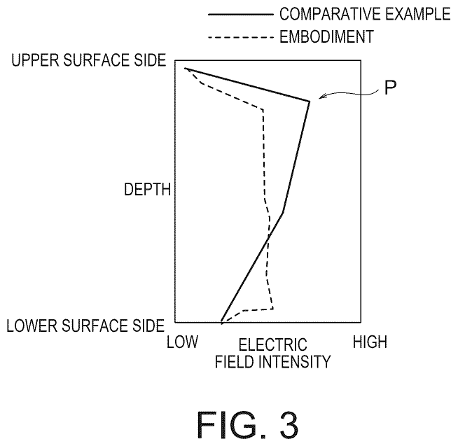

FIG. 3 is a graph showing electric field intensities of the first semiconductor regions in the semiconductor devices according to the first embodiment and a comparative example. More specifically, FIG. 3 illustrates distributions of electric field intensities in the first semiconductor regions when reverse voltages are applied between drain electrodes and source electrodes (not illustrated) (at the time of reverse bias). As described above, in the semiconductor device 1 according to the present embodiment, the resistivity of the epitaxial growth layers 21 to 23 increases in the order of the epitaxial growth layers 21, 22, and 23. Meanwhile, the comparative example illustrated in FIG. 3 corresponds to, for example, a case where the resistivity of the epitaxial growth layers 21 to 23 is identical, and the FP electrode 13 and the insulating regions 41 to 46 are not provided. In addition, the electric field intensities of the first embodiment illustrated in FIG. 3 are measured by applying 0 V to all of the FP electrodes 13 in the insulating regions 41 to 46 in FIG. 2.

As illustrated in FIG. 3, in the semiconductor device 1 according to the present embodiment, since the resistivity increases in the order of the epitaxial growth layers 21, 22, and 23, the electric field intensity becomes uniform at the time of reverse bias. That is, in the present embodiment, a withstand voltage can be secured for the entire first semiconductor region at the time of reverse bias. Meanwhile, in the semiconductor device according to the comparative example, the electric field intensity is not uniform at the time of reverse bias, and the electric field intensity has a peak P. Therefore, the withstand voltage of the semiconductor device according to the comparative example is determined by the electric field intensity at the peak P, and the withstand voltage decreases as a whole. Accordingly, in the present embodiment, since the resistivity increases in the order of the epitaxial growth layers 21, 22, and 23, it is possible to alleviate the electric field concentration in the first semiconductor region and improve the withstand voltage of the semiconductor device 1. Also, for this reason, it is possible to perform Quality Control (QC) of the semiconductor device 1 by measuring the resistivity of the epitaxial growth layers 21 to 23.

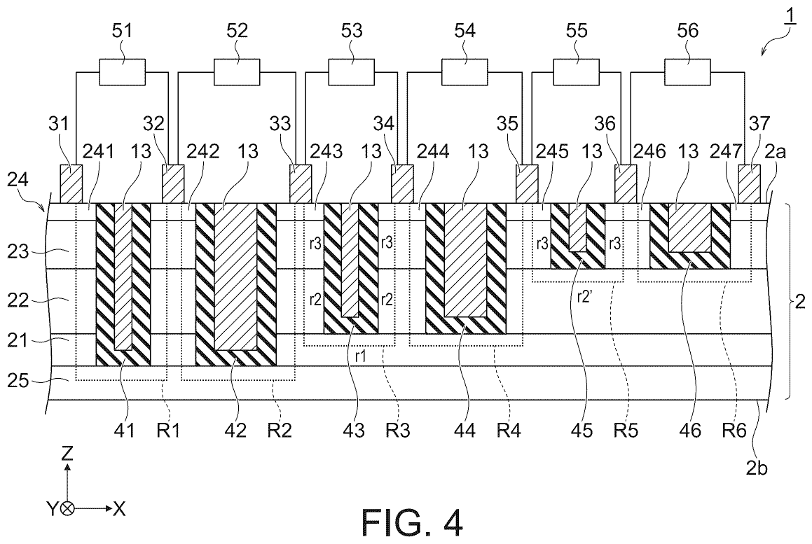

Next, an operation example of the semiconductor device 1 for measuring the resistivity of the epitaxial growth layers 21 to 23 is described with reference to FIG. 4. FIG. 4 is a schematic cross-sectional view illustrating an operation example of the semiconductor device 1 according to the first embodiment.

As illustrated in FIG. 4, the measurement units 51 to 56 are electrically connected to the contact portions 31 to 37 of the semiconductor device 1, respectively. The measurement units 51 to 56 are devices that respectively measure resistance values in the paths R1 to R6 as the resistance values between the contact portions of each contact pair.

More specifically, the measurement unit 51 is electrically connected to the contact portion 31 and the contact portion 32 and measures a resistance value (direct-current resistance value) between the contact portions 31 and 32. This resistance value is, for example, a resistance value in the path R1 of FIG. 4. The path R1 is a current path that passes through the epitaxial growth layers 21 to 23 based on the thicknesses (lengths in the Z-axis direction) of the epitaxial growth layers 21 to 23 and passes through the substrate 25 based on the width of the insulating region 41. Note that, in the resistance value of the path R1, the resistance value by the high-concentration layer 24 is sufficiently smaller than the resistance value by the epitaxial growth layers 21 to 23 and the substrate 25 and thus is omitted. The same applies to the resistance values of the subsequent paths R2 to R6.

The measurement unit 52 is electrically connected to the contact portion 32 and the contact portion 33 and measures a resistance value between the contact portions 32 and 33. This resistance value is, for example, a resistance value in the path R2 of FIG. 4. The path R2 is a current path that passes through the epitaxial growth layers 21 to 23 based on the thicknesses of the epitaxial growth layers 21 to 23 and passes through the substrate 25 based on the width of the insulating region 42.

The measurement unit 53 is electrically connected to the contact portion 33 and the contact portion 34 and measures a resistance value between the contact portions 33 and 34. This resistance value is, for example, a resistance value in the path R3 of FIG. 4. The path R3 is a current path that passes through the epitaxial growth layers 22 and 23 based on the thicknesses of the epitaxial growth layers 22 and 23 and passes through the epitaxial growth layer 21 based on the width of the insulating region 43. Specifically, the resistance value of the path R3 is expressed as r1+2·r2+2·r3 using a resistance value r1 of the portion passing through the epitaxial growth layer 21, a resistance value r2 of the portion passing through the epitaxial growth layer 22, and a resistance value r3 of the portion passing through the epitaxial growth layer 23. The resistance value in the path R3 is an example of a first resistance value.

The measurement unit 54 is electrically connected to the contact portion 34 and the contact portion 35 and measures a resistance value between the contact portions 34 and 35. This resistance value is, for example, a resistance value in the path R4 of FIG. 4. The path R4 is a current path that passes through the epitaxial growth layers 22 and 23 based on the thicknesses of the epitaxial growth layers 22 and 23 and passes through the epitaxial growth layer 21 based on the width of the insulating region 44.

The measurement unit 55 is electrically connected to the contact portion 35 and the contact portion 36 and measures a resistance value between the contact portions 35 and 36. This resistance value is, for example, a resistance value in the path R5 of FIG. 4. The path R5 is a current path that passes through the epitaxial growth layer 23 based on the thicknesses of the epitaxial growth layer 23 and passes through the epitaxial growth layer 22 based on the width of the insulating region 45. Specifically, the resistance value of the path R5 is expressed as r2′+2·r3 using a resistance value r2′ of the portion passing through the epitaxial growth layer 22 and the resistance value r3 of the portion passing through the epitaxial growth layer 23. The resistance value in the path R5 is an example of a second resistance value.

The measurement unit 56 is electrically connected to the contact portion 36 and the contact portion 37 and measures a resistance value between the contact portions 36 and 37. This resistance value is, for example, a resistance value in the path R6 of FIG. 4. The path R6 is a current path that passes through the epitaxial growth layer 23 based on the thicknesses of the epitaxial growth layer 23 and passes through the epitaxial growth layer 22 based on the width of the insulating region 46.

As described above, the semiconductor device 1 according to the present embodiment includes the first semiconductor region, the insulating region 43, the insulating region 45, the high-concentration layers 243 and 244, the high-concentration layers 245 and 246, the first contact pair, and the second contact pair. In the first semiconductor region, an n-type or p-type impurity concentration decreases from the lower surface toward the upper surface along the Z-axis direction that is a thickness direction. The insulating region 43 is provided from the upper surface of the first semiconductor region toward the lower surface of the first semiconductor region, has a lower end positioned at a height at which the impurity concentration of the first semiconductor region is a first concentration, and extends in the Y-axis direction orthogonal to the Z-axis direction. The insulating region 45 is provided from the upper surface of the first semiconductor region toward the lower surface of the first semiconductor region, has the lower end positioned at a height at which the impurity concentration of the first semiconductor region is a second concentration lower than the first concentration, and extends in the Y-axis direction. The high-concentration layers 243 and 244 are provided on the upper surface of the first semiconductor region so as to sandwich the insulating region 43 in the X-axis direction orthogonal to the Z-axis direction and the Y-axis direction. The high-concentration layers 245 and 246 are provided on the upper surface of the first semiconductor region so as to sandwich the insulating region 45 in the X-axis direction. The first contact pair includes the contact portion 33 electrically connected to the high-concentration layer 243 and the contact portion 34 electrically connected to the high-concentration layer 244. The second contact pair includes the contact portion 35 electrically connected to the high-concentration layer 245 and the contact portion 36 electrically connected to the high-concentration layer 246.

According to the semiconductor device 1 according to the present embodiment, the resistivity of the epitaxial growth layers 21 to 23 can be calculated from the resistance values of the paths R1 to R6 measured by the measurement units 51 to 56, and the quality of the epitaxial growth layers 21 to 23 can be easily inspected.

Specifically, for example, a difference r1−r2′+2·r2 between the resistance value of the path R3 and the resistance value of the path R5 is calculated from the resistance value r1+2·r2+2·r3 of the path R3 measured by the measurement unit 53 and the resistance value r2′30 2·r3 of the path R5 measured by the measurement unit 55. From this difference and the widths (lengths in the X-axis direction) and heights (lengths in the Z-axis direction) of the insulating regions 43 and 45, a value related to the resistivity of the epitaxial growth layers 21 and 22 is calculated. Further, when the difference between r1 and r2′ is negligible compared to 2·r2, the difference is 2·r2. In this case, the resistivity of the epitaxial growth layer 22 can be calculated by dividing the value r2 obtained by dividing the difference by 2 by the difference between the heights of the insulating regions 43 and 45. Examples of the case where the difference between r1 and r2′ is negligible as compared with 2·r2 include a case where the widths of the insulating regions 43 and 45 with respect to the difference between the heights of the insulating regions 43 and 45 are sufficiently small. In this case, the quality of the epitaxial growth layer 22 can be easily and more appropriately inspected.

In addition, the semiconductor device 1 according to the present embodiment includes the insulating region 44 of which the height of the lower end is the same as that of the insulating region 43 and the width is different from that of the insulating region 43. Therefore, for example, the contribution of the epitaxial growth layer 21 in the resistance values of the paths R3 and R4 can be excluded based on the resistance values of the paths R3 and R4 and the widths of the insulating regions 43 and 44. Similarly, the contribution of the epitaxial growth layer 22 in the resistance values of the paths R5 and R6 can be excluded based on the resistance values of the paths R5 and R6 and the widths of the insulating regions 45 and 46. Then, the resistivity of the epitaxial growth layers 22 and 23 can be calculated based on the resistance values of the paths R3 to R6 excluding the contribution of the epitaxial growth layers 21 and 22 and the height of the insulating regions 43 to 46. Therefore, the qualities of the epitaxial growth layers 22 and 23 can be easily and more appropriately inspected.

In addition, the semiconductor device 1 according to the present embodiment includes the insulating regions 41 and 42 whose lower ends are positioned at a height at which the impurity concentration of the first semiconductor region is higher than the first concentration and whose widths are different from each other. Therefore, for example, the contribution of the substrate 25 in the resistance values of the paths R1 and R2 can be excluded based on the resistance values of the paths R1 and R2 and the widths of the insulating regions 41 and 42. Then, for example, the resistivity of the substrate 25 can be calculated based on the resistance values of the paths R1 to R3 excluding the contribution of the substrate 25 and the heights of the insulating regions 41 to 43. As a result, for example, the relationship between the resistivity of the epitaxial growth layers 21 to 23 and the resistivity of the substrate 25 can be inspected, and the qualities of the epitaxial growth layers 21 to 23 can be easily and more appropriately inspected.

Note that in the present embodiment, the resistivity of the substrate 25 may be calculated based on the resistance values of the paths R1 and R2 and the widths of the insulating regions 41 and 42. Also, the resistivity of the epitaxial growth layer 21 may be calculated based on the resistance values of the paths R3 and R4 and the widths of the insulating regions 43 and 44. Also, the resistivity of the epitaxial growth layer 22 may be calculated based on the resistance values of the paths R5 and R6 and the widths of the insulating regions 45 and 46. That is, since the semiconductor device 1 includes at least the insulating regions 43 and 44, the resistivity of the epitaxial growth layer 21 can be calculated by dividing a value obtained by subtracting the resistance value of the path R3 from the resistance value of the path R4 by a value obtained by subtracting the width of the insulating region 43 from the width of the insulating region 44. Therefore, the quality of the epitaxial growth layer 21 can be easily inspected. Similarly, since the semiconductor device 1 includes at least the insulating regions 45 and 46, the resistivity of the epitaxial growth layer 22 can be calculated by dividing a value obtained by subtracting the resistance value of the path R5 from the resistance value of the path R6 by a value obtained by subtracting the width of the insulating region 45 from the width of the insulating region 46. Therefore, the quality of the epitaxial growth layer 22 can be easily inspected.

Therefore, according to the semiconductor device 1 according to the present embodiment, the resistivity of substrate 25 and the epitaxial growth layer 21 to 22 can be calculated from the resistance values measured by the measurement units 51 to 56 and the widths and heights of the insulating regions 41 to 46.

Note that, for example, in the resistance value r1+2·r2+2·r3 of the path R3, when a contribution r1 by the epitaxial growth layer 21 is negligible compared to the contributions r2 and r3 by the epitaxial growth layers 22 and 23, the insulating region 44 may be omitted. Similarly, in the resistance value of the path R5, when a contribution r2′ by the epitaxial growth layer 22 is negligible as compared with a contribution r3 by the epitaxial growth layer 23, the insulating region 45 may be omitted.

In addition, the semiconductor wafer may have the above structure. That is, by using a semiconductor wafer including the epitaxial growth layers 21 to 23, the high-concentration layer 24, the substrate 25, and the insulating regions 41 to 46 described above, the qualities of the epitaxial growth layers 21 to 23 in the semiconductor wafer can be easily inspected. Also, in this case, the epitaxial growth layers 21 to 23, the high-concentration layer 24, the substrate 25, and the insulating regions 41 to 46 may be arranged on a dicing line of the semiconductor wafer.

### Method For Manufacturing Semiconductor Device 1

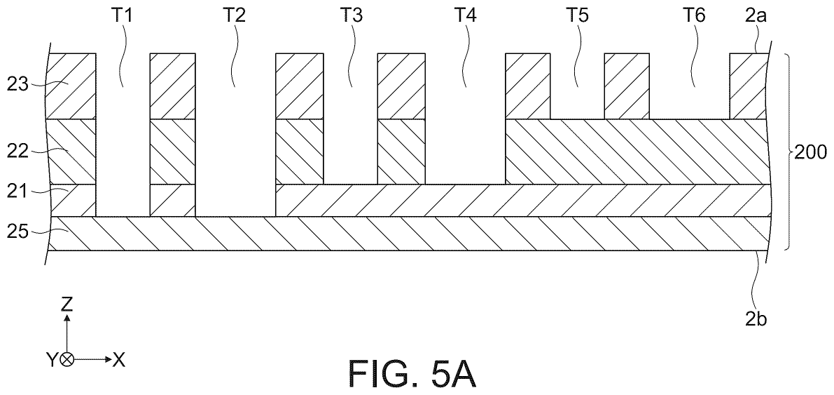

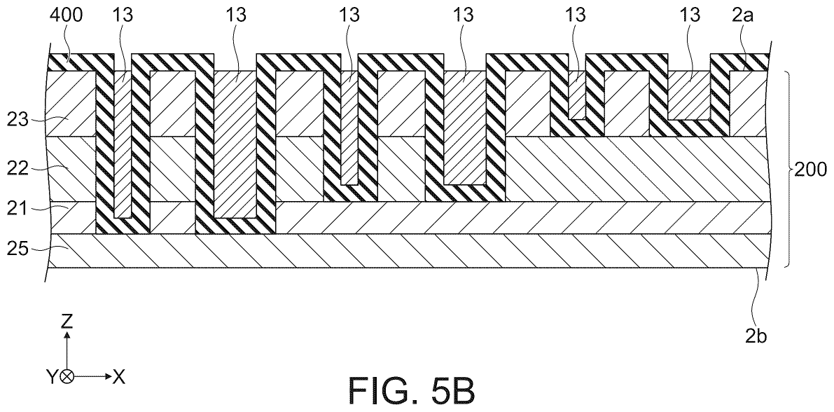

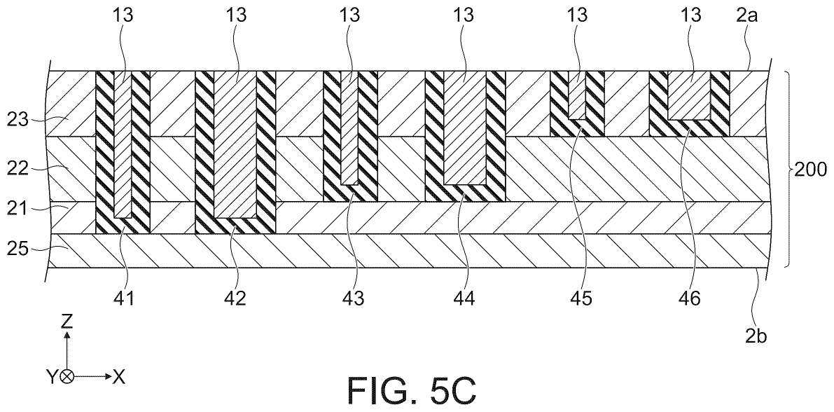

Next, an example of a method for manufacturing the semiconductor device 1 according to the present embodiment will be described with reference to FIGS. 5A to 5C. FIGS. 5A to 5C are cross-sectional views for describing an example of a manufacturing process of the semiconductor device 1 according to the first embodiment.

First, as illustrated in FIG. 5A, a semiconductor wafer 200 is prepared. The semiconductor wafer 200 includes the epitaxial growth layer 21, the epitaxial growth layer 22, the epitaxial growth layer 23, and the substrate 25. In addition, the semiconductor wafer 200 includes trenches T1 to T6 formed from the upper surface 2a toward the lower surface. The trenches T1 to T6 are trenches in which the FP electrode 13 and the insulating regions 41 to 46 are to be formed in a later process.

Note that the semiconductor wafer 200 is formed, for example, as follows. First, the substrate 25 is prepared. Thereafter, the epitaxial growth layer 21 having n-type impurities of the first concentration is epitaxially grown on the upper surface of the substrate 25. Thereafter, the epitaxial growth layer 22 having n-type impurities of the second concentration is epitaxially grown on the upper surface of the epitaxial growth layer 21. Thereafter, the epitaxial growth layer 23 having n-type impurities of the third concentration is epitaxially grown on the upper surface of the epitaxial growth layer 23.

Thereafter, the trenches T1 to T6 are formed. For example, first, a resist film is formed on the upper surface 2a of the semiconductor wafer 200 other than the portions where the trenches T1 and T2 are to be formed. Thereafter, the trench T1 and the trench T2 are formed by reactive ion etching (RIE) or the like using a resist film as a mask. Thereafter, the resist film is removed.

Thereafter, a resist film is formed on the upper surface 2a of the semiconductor wafer 200 other than the portions where the trench T3 and the trench T4 are to be formed. Thereafter, the trench T3 and the trench T4 are formed by RIE or the like using a resist film as a mask. The RIE in this process is performed under different conditions from when the trenches T1 and T2 are formed. Thus, the trenches T3 and T4 having different depths from the trenches T1 and T2 can be formed. Thereafter, the resist film is removed.

Thereafter, a resist film is formed on the upper surface 2a of the semiconductor wafer 200 other than the portions where the trench T5 and the trench T6 are to be formed. Thereafter, the trench T5 and the trench T6 are formed by RIE or the like using a resist film as a mask. The RIE in this process is performed under different conditions from when the trenches T1 to T4 are formed. Thus, the trenches T5 and T6 having different depths from the trenches T1 to T4 can be formed.

Through the above steps, the semiconductor wafer 200 is formed. Note that the order of forming the trenches T1 to T6 is not limited to the above-described example and is arbitrary.

Next, as illustrated in FIG. 5B, an insulating region 400 is formed on the inner walls of the trenches T1 to T6 and the upper surface 2a of the semiconductor wafer 200 by thermal oxidation or the like. Thereafter, a conductive material such as polysilicon is deposited in the insulating region 400 in the trenches T1 to T6 by chemical vapor deposition (CVD) or the like. Thereafter, the conductive material is etched back by chemical mechanical polishing (CMP), chemical dry etching (CDE), or the like. As a result, the FP electrode 13 is formed.

Next, as illustrated in FIG. 5C, thereafter, a portion positioned above the upper surface 2a of the semiconductor wafer 200 in the insulating region is removed by RIE or the like. As a result, the insulating regions 41 to 46 remain in the trenches T1 to T6, respectively.

Thereafter, although not illustrated, impurities having the same conductivity type as that of the epitaxial growth layers 21 to 23 are ion-implanted into the upper surface 2a of the semiconductor wafer 200 to form the high-concentration layer 24 (the high-concentration layers 241 to 247). Thereafter, the contact portions 31 to 37 electrically connected to the high-concentration layers 241 to 247 are formed. Thereafter, the semiconductor wafer 200 is diced into a plurality of semiconductor devices 1. Through the above process, the semiconductor device 1 is manufactured.

### Modification of First Embodiment

In the first embodiment described above, the insulating regions 42, 44, and 46 of which the heights of the lower ends are respectively the same as those of the insulating regions 41, 43, and 45 and widths are respectively different from those of the insulating regions 41, 43, and 45 are formed. The present invention is not limited thereto, and insulating regions respectively having the same heights of the lower ends and the same widths as those of the insulating regions 41, 43, and 45 may be formed. Hereinafter, such a case is described as a modification of the first embodiment, and differences from the above-described first embodiment are mainly described.

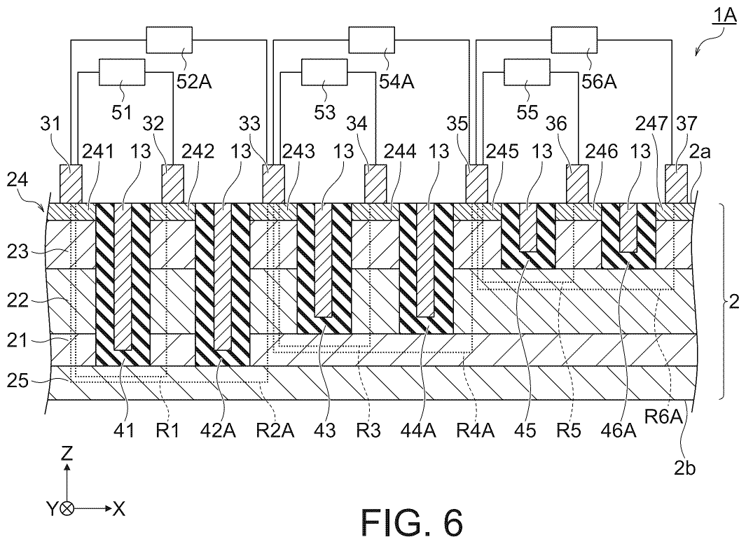

FIG. 6 is a cross-sectional view of an operation example of a semiconductor device 1A according to a modification of the first embodiment. As illustrated in FIG. 6, the semiconductor device 1A according to the present modification includes insulating regions 42A, 44A, and 46A instead of the insulating regions 42, 44, and 46 of the semiconductor device 1 according to the first embodiment, respectively.

The lower end of the insulating region 42A is positioned at the same height as that of the insulating region 41. Also, the insulating region 42A has the same width as the insulating region 41. Also, the insulating region 42A is adjacent to the insulating region 41 in the X-axis direction. That is, another insulating region (such as the insulating region 43) of which the height of the lower end is different from those of the insulating region 41 and the insulating region 42A is not provided between the insulating region 41 and the insulating region 42A in the X-axis direction.

The lower end of the insulating region 44A is positioned at the same height as that of the insulating region 43. Also, the insulating region 44A has the same width as the insulating region 43. Also, the insulating region 44A is adjacent to the insulating region 43 in the X-axis direction.

The lower end of the insulating region 46A is positioned at the same height as that of the insulating region 45. Also, the insulating region 46A has the same width as the insulating region 45. Also, the insulating region 46A is adjacent to the insulating region 45 in the X-axis direction.

In the present modification, measurement units 52A, 54A, and 56A are connected instead of the measurement units 52, 54, and 56, and resistance values of paths R2A, R4A, and R6A are measured instead of the resistance values of the paths R2, R4, and R6 in the first embodiment.

More specifically, the measurement unit 52A is electrically connected to the contact portion 31 and the contact portion 33 and measures a resistance value between the contact portions 31 and 33. This resistance value is, for example, a resistance value in the path R2A of FIG. 6. The path R2A is a current path that passes through the epitaxial growth layers 21 to 23 based on the thicknesses of the epitaxial growth layers 21 to 23 and passes through the substrate 25 based on the widths of the insulating region 41 and the insulating region 42A and the width of the first semiconductor region between the insulating region 41 and the insulating region 42A.

The measurement unit 54A is electrically connected to the contact portion 33 and the contact portion 35 and measures a resistance value between the contact portions 33 and 35. This resistance value is, for example, a resistance value in the path R4A of FIG. 6. The path R4A is a current path that passes through the epitaxial growth layers 22 and 23 based on the respective thicknesses of the epitaxial growth layers 22 and 23 and passes through the epitaxial growth layer 21 based on the widths of the insulating region 43 and the insulating region 44A and the width of the first semiconductor region between the insulating region 43 and the insulating region 44A.

The measurement unit 56A is electrically connected to the contact portion 35 and the contact portion 37 and measures a resistance value between the contact portions 35 and 37. This resistance value is, for example, a resistance value in the path R6A of FIG. 6. The path R6A is a current path that passes through the epitaxial growth layer 23 based on the thickness of the epitaxial growth layer 23 and passes through the epitaxial growth layer 22 based on the widths of the insulating region 45 and the insulating region 46A and the width of the first semiconductor region between the insulating region 45 and the insulating region 46A.

In the present modification, the path R1 and the path R2A have the same distance in the epitaxial growth layers 21 to 23 but have different distances in the substrate 25. Therefore, the contribution of the substrate 25 in the resistance values of the paths R1 and R2A can be excluded based on the resistance values of the paths R1 and R2A and the widths of the insulating regions 41 and 42A.

Similarly, the path R3 and the path R4A have the same distance in the epitaxial growth layers 22 and 23 but have different distances in the epitaxial growth layer 21. Therefore, the contribution of the epitaxial growth layer 21 in the resistance values of the paths R3 and R4A can be excluded based on the resistance values of the paths R3 and R4A and the widths of the insulating regions 43 and 44A.

Similarly, the path R5 and the path R6A have the same distance in the epitaxial growth layer 23 but have different distances in the epitaxial growth layer 22. Therefore, the contribution of the epitaxial growth layer 22 in the resistance values of the paths R5 and R6A can be excluded based on the resistance values of the paths R5 and R6A and the widths of the insulating regions 45 and 46A.

Therefore, according to the semiconductor device 1A according to the present modification, it is possible to calculate the resistivity of the substrate 25 and the epitaxial growth layers 21 and 22 and the resistivity of the epitaxial growth layer 23 from the resistance values measured by the measurement units 51, 52A, 53, 54A, 55, and 56A and the widths and heights of the insulating regions 41, 42A, 43, 44A, 45, and 46A. Therefore, similarly to the first embodiment, the qualities of the epitaxial growth layers 21 to 23 can be easily inspected.

### Second Embodiment

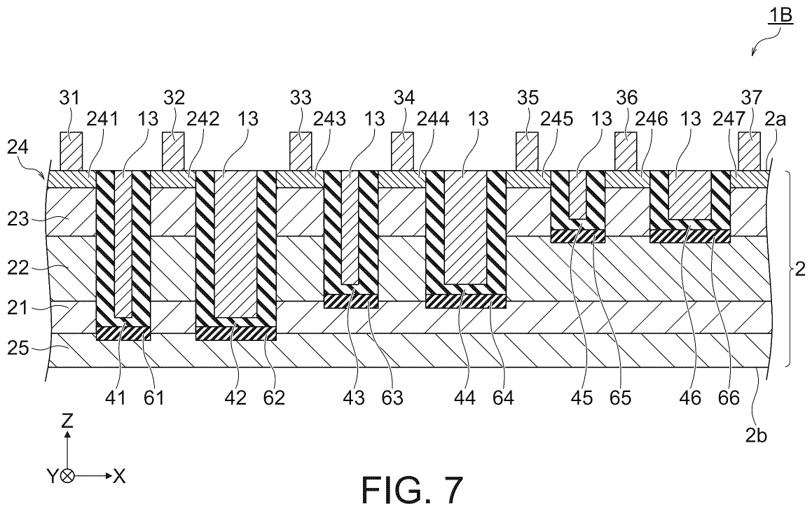

Next, a second embodiment in which a stopper film is provided under the insulating regions 41 to 46 is described focusing on differences from the above-described first embodiment. FIG. 7 is a cross-sectional view of a semiconductor device according to a second embodiment.

As illustrated in FIG. 7, a semiconductor device 1B according to the present embodiment includes insulating regions 61 to 66 provided between the bottoms of the insulating regions 41 to 46 and the first semiconductor region in addition to each portion of the semiconductor device 1 according to the first embodiment. The insulating regions 61 to 66 include, for example, silicon oxide or silicon nitride. The insulating regions 61 to 66 are formed, for example, by thermal oxidation of insulating regions 610 to 660 described below, which are stopper films.

The insulating region 61 is sandwiched between the bottom of the insulating region 41 and the first semiconductor region. The insulating region 61 has, for example, the same width as the insulating region 41. In the present embodiment, the lower end of the insulating region 61 is positioned under as the boundary between the substrate 25 and the epitaxial growth layer 21.

The insulating region 62 is sandwiched between the bottom of the insulating region 42 and the first semiconductor region. The insulating region 62 has, for example, the same width as the insulating region 42. In the present embodiment, the lower end of the insulating region 62 is positioned under the boundary between the substrate 25 and the epitaxial growth layer 21.

The insulating region 63 is sandwiched between the bottom of the insulating region 43 and the first semiconductor region. The insulating region 63 has, for example, the same width as the insulating region 43. In the present embodiment, the lower end of the insulating region 63 is positioned under the boundary between the epitaxial growth layer 21 and the epitaxial growth layer 22. The insulating region 63 is an example of a sixth insulating region in the claims.

The insulating region 64 is sandwiched between the bottom of the insulating region 44 and the first semiconductor region. The insulating region 64 has, for example, the same width as the insulating region 44. In the present embodiment, the lower end of the insulating region 64 is positioned under the boundary between the epitaxial growth layer 21 and the epitaxial growth layer 22.

The insulating region 65 is sandwiched between the bottom of the insulating region 45 and the first semiconductor region. The insulating region 65 has, for example, the same width as the insulating region 45. In the present embodiment, the lower end of the insulating region 65 is positioned under the boundary between the epitaxial growth layer 22 and the epitaxial growth layer 23. The insulating region 65 is an example of a seventh insulating region in the claims.

The insulating region 66 is sandwiched between the bottom of the insulating region 46 and the first semiconductor region. The insulating region 66 has, for example, the same width as the insulating region 46. In the present embodiment, the lower end of the insulating region 66 is positioned under the boundary between the epitaxial growth layer 22 and the epitaxial growth layer 23.

In the present embodiment, for each insulating region of the insulating regions 41 to 46, the distance between the insulating region and the semiconductor layer 2 in the Z-axis direction is longer than the distance between the insulating region and the semiconductor layer 2 in the X-axis direction.

According to the present embodiment, the manufacturing process of the semiconductor device 1B described below can be simplified.

### Method For Manufacturing Semiconductor Device 1B

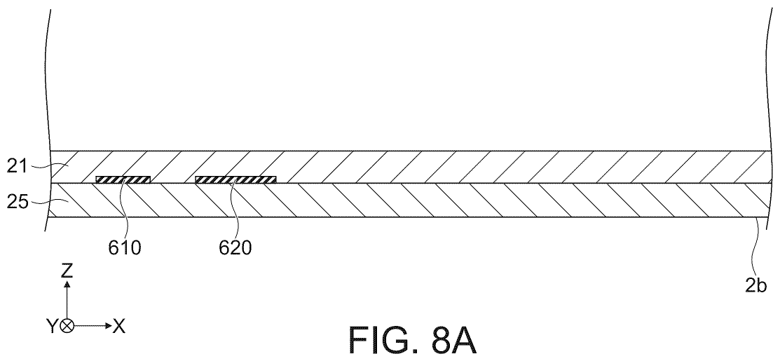

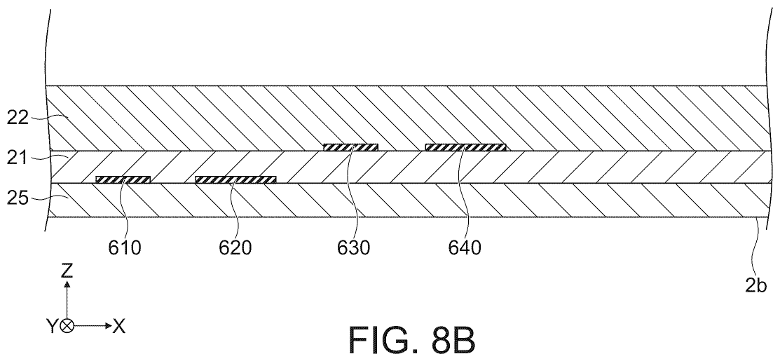

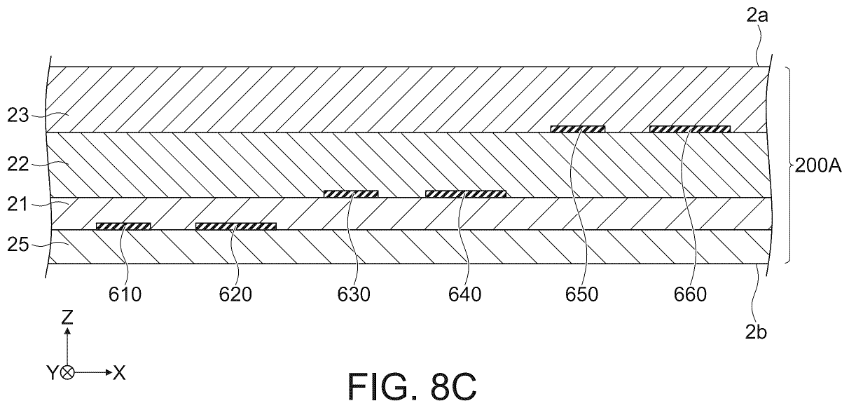

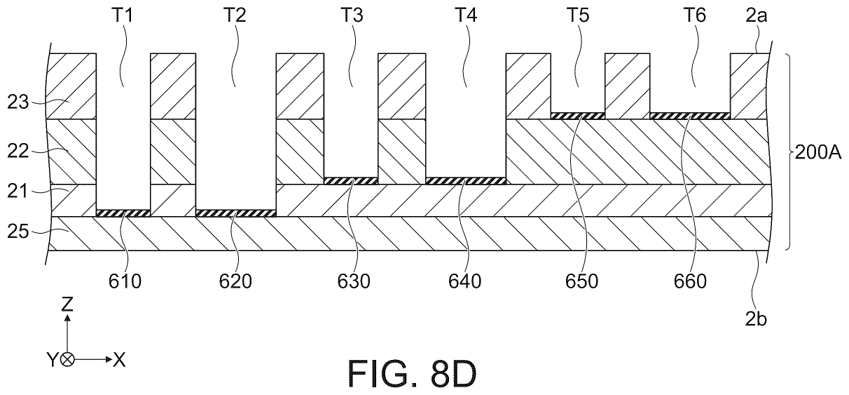

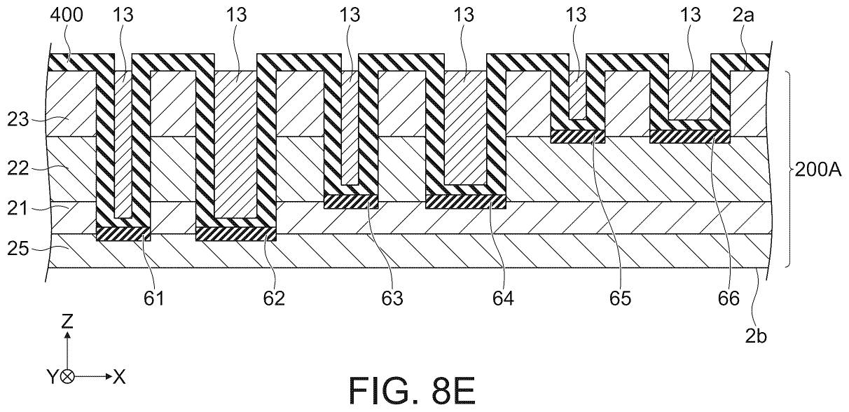

Next, an example of a method for manufacturing the semiconductor device 1B according to the present embodiment is described with reference to FIGS. 8A to 8E. FIGS. 8A to 8E are cross-sectional views illustrating an example of a manufacturing process of the semiconductor device 1B according to the second embodiment.

First, a semiconductor wafer member illustrated in FIG. 8A is prepared. The semiconductor wafer member includes the epitaxial growth layer 21, the substrate 25, an insulating region 610, and an insulating region 620.

Note that the semiconductor wafer member illustrated in FIG. 8A is formed, for example, as follows. First, the substrate 25 is prepared. Thereafter, an insulating material is deposited on a portion of the upper surface of the substrate 25 by CVD, wet etching, or the like to form the insulating region 610 and the insulating region 620. The insulating region 610 and the insulating region 620 are examples of a first stopper film. Thereafter, the epitaxial growth layer 21 having n-type impurities of the first concentration is epitaxially grown on the upper surface of the substrate 25. The epitaxial growth layer 21 buries the insulating region 610 and the insulating region 620. Note that the lower ends of the insulating region 610 and the insulating region 620 are positioned at the boundary between the substrate 25 and the epitaxial growth layer 21.

Next, as illustrated in FIG. 8B, an insulating material is deposited on a part of the upper surface of the epitaxial growth layer 21 by CVD, wet etching, or the like to form an insulating region 630 and an insulating region 640. The insulating region 630 and the insulating region 640 are examples of a second stopper film. Thereafter, the epitaxial growth layer 22 having n-type impurities of the second concentration is epitaxially grown on the upper surface of the epitaxial growth layer 21. The epitaxial growth layer 22 buries the insulating region 630 and the insulating region 640. Note that the lower ends of the insulating region 630 and the insulating region 640 are positioned at the boundary between the epitaxial growth layer 21 and the epitaxial growth layer 22.

Next, as illustrated in FIG. 8C, an insulating material is deposited on a part of the upper surface of the epitaxial growth layer 22 by CVD, wet etching, or the like to form an insulating region 650 and an insulating region 660. The insulating region 650 and the insulating region 660 are examples of a third stopper film. Thereafter, the epitaxial growth layer 23 having n-type impurities of the third concentration is epitaxially grown on the upper surface of the epitaxial growth layer 22. The epitaxial growth layer 23 buries the insulating region 650 and the insulating region 660. Note that the lower ends of the insulating region 650 and the insulating region 660 are positioned at the boundary between the epitaxial growth layer 22 and the epitaxial growth layer 23. As a result of this process, a semiconductor wafer 200A is formed.

Next, as illustrated in FIG. 8D, the trenches T1 to T6 are formed. More specifically, first, a resist film is formed on the upper surface 2a of the semiconductor wafer 200A other than the portion where the trenches T1 to T6 are to be formed. Thereafter, the trenches T1 to T6 are formed by RIE or the like using the resist film as a mask and using the insulating region 610 to the insulating region 660 as stopper films.

Next, as illustrated in FIG. 8E, the insulating region 400 is formed on the inner walls of the trenches T1 to T6 and the upper surface 2a of the semiconductor wafer 200A by thermal oxidation or the like. In the present embodiment, in this process, the insulating region 610 to the insulating region 660 become the insulating region 61 to the insulating region 66, respectively.

Note that, in the present embodiment, in the process illustrated in FIG. 8E, since the insulating region extends also to the first semiconductor region positioned under the insulating region 610 to the insulating region 660, the lower ends of the insulating region 61 to the insulating region 66 are positioned under the lower ends of the insulating region 610 to the insulating region 660. More specifically, the lower ends of the insulating regions 610 and 620 are positioned under the boundary between the substrate 25 and the epitaxial growth layer 21. In addition, the lower ends of the insulating regions 63 and 64 are positioned under the boundary between the epitaxial growth layer 21 and the epitaxial growth layer 22. In addition, the lower ends of the insulating regions 65 and 66 are positioned under the boundary between the epitaxial growth layer 22 and the epitaxial growth layer 23.

The subsequent processes are similar to those in the first embodiment. Accordingly, the semiconductor device 1B according to the present embodiment is manufactured.

According to the method for manufacturing the semiconductor device 1B according to the present embodiment, the trenches T1 to T6 can be collectively formed. Therefore, the manufacturing process of the semiconductor device 1B can be simplified.

### Third Embodiment

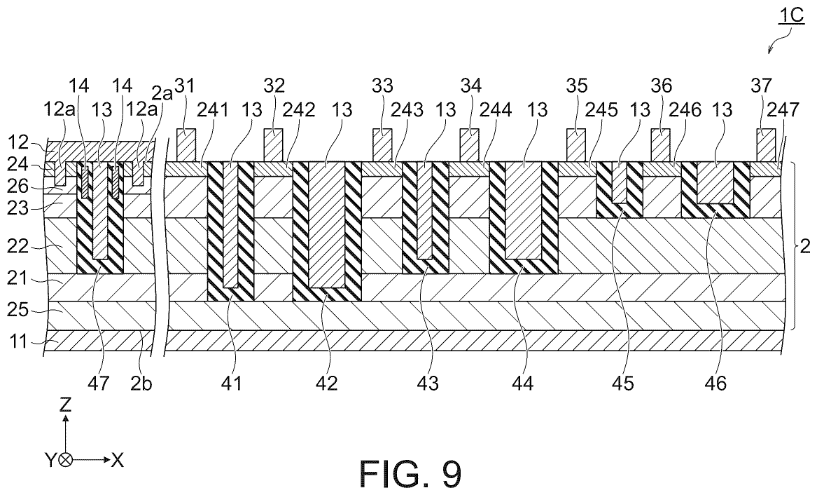

Next, a third embodiment in which the semiconductor device 1 according to the first embodiment is incorporated in a metal oxide semiconductor field effect transistor (MOSFET) is described. FIG. 9 is a cross-sectional view of a semiconductor device 1C according to the third embodiment. Hereinafter, the semiconductor device 1C according to the present embodiment is described focusing on the differences from the first embodiment. In addition, in the following description, a case where a semiconductor device 1C is a vertical MOSFET is described. Note that the semiconductor device 1C may be a transistor such as an insulated gate bipolar transistor (IGBT) or a diode. Further, the semiconductor device 1C may be a horizontal device.

As illustrated in FIG. 9, in addition to each part of the semiconductor device 1 according to the first embodiment, the semiconductor device 1C according to the present embodiment includes a drain electrode 11, a source electrode 12, a gate electrode 14, a base region 26, and an insulating region 47.

In the following description, a region functioning as a MOSFET in the semiconductor device 1C is referred to as a cell region, and a region positioned at a terminal end of the MOSFET is referred to as a terminal region. The cell region is a region through which a current flows between the drain electrode 11 and the source electrode 12. Also, the termination region is, for example, a region provided so as to surround the cell region on a plane orthogonal to the Z-axis direction. In the present embodiment, the source electrode 12, the gate electrode 14, the base region 26, and the insulating region 47 are provided in the cell region. The insulating regions 41 to 46 and the contact portions 31 to 37 are provided in the termination region. Note that the insulating regions 41 to 46 and the contact portions 31 to 37 may be provided in the cell region.

The drain electrode 11 functions as a drain electrode of the MOSFET. The drain electrode 11 is provided on the lower surface 2b of the semiconductor layer 2. The drain electrode 11 is electrically connected to the substrate 25 in the cell region. The drain electrode 11 includes, for example, at least one of copper (Cu), titanium (Ti), tungsten (W), and aluminum (Al). The drain electrode 11 is an example of a first electrode.

The source electrode 12 functions as a source electrode of the MOSFET. The source electrode 12 is provided on the upper surface 2a in the cell region of the semiconductor layer 2. The source electrode 12 is electrically connected to the FP electrode 13 and the high-concentration layer 24 in the cell region. In addition, the source electrode 12 includes a contact portion 12a protruding downward in FIG. 9. The contact portion 12a penetrates the high-concentration layer 24 and reaches the base region 26. The source electrode 12 is electrically connected to the base region 26 via the contact portion 12a. Note that, although not illustrated, the source electrode 12 may be electrically connected to the FP electrode 13 in the insulating regions 41 to 46. The source electrode 12 includes, for example, at least one of copper (Cu), titanium (Ti), tungsten (W), and aluminum (Al). The source electrode 12 is an example of a second electrode.

The gate electrode 14 functions as a gate electrode of the MOSFET. The gate electrode 14 is provided in the insulating region 47 so as to face the base region 26 via the insulating region 47 in the X-axis direction. The gate electrode 14 is electrically insulated from the semiconductor layer 2 by the insulating region 47. The gate electrode 14 is made of, for example, polysilicon containing p-type or n-type impurities. When a voltage is applied to the gate electrode 14, a channel is formed in the base region 26 in a portion facing the gate electrode 14, and carriers (electrons or holes) flow between the epitaxial growth layer 23 and the high-concentration layer 24. As a result, the MOSFET is brought into an on-state.

The base region 26 functions as a base region of the MOSFET. In the present embodiment, the base region 26 is provided in the cell region and is positioned on the epitaxial growth layer 23. The base region 26 includes impurities having a conductivity type different from those of the epitaxial growth layers 21 to 23 and the substrate 25 (the first semiconductor region). In the present embodiment, the base region 26 is a p-type semiconductor region. The base region 26 configures a second semiconductor region. The p-type impurity concentration of the base region 26 is, for example, 1×10¹⁶ cm⁻³ to 1×10²⁰ cm⁻³.

The insulating region 47 is provided from the upper surface of the first semiconductor region toward the lower surface of the first semiconductor region. Note that the insulating region 47 includes, for example, a silicon oxide or a silicon nitride. In the present embodiment, the lower end of the insulating region 47 is positioned at the same height as the lower ends of the insulating regions 43 and 44. As a result, the insulating regions 43 and 44 and the insulating region 47 can be collectively formed. Note that the height of the lower end of the insulating region 47 is arbitrary. For example, the lower end of the insulating region 47 may be positioned at the same height as the lower ends of the insulating regions 41 and 42, may be positioned at the same height as the lower ends of the insulating regions 45 and 46, or may be positioned at other heights.

In addition, in the example of FIG. 9, the upper portion of the epitaxial growth layers 21 to 23 and the substrate 25 in the cell region function as drift region of the MOSFET. In addition, the high-concentration layer 24 in the cell region functions as a source region of the MOSFET. Also, the lower portion of the substrate 25 in the cell region functions as a drain region of the MOSFET.

Note that a drain region for ensuring ohmic contact with the drain electrode 11 may be provided on the lower surface 2b of the semiconductor layer 2 in the cell region. The drain region includes impurities having the same conductivity type as that of the epitaxial growth layers 21 to 23 and the substrate 25 (the first semiconductor region). Also, an impurity concentration of the drain region is, for example, 1×10¹⁸ cm⁻³ to 1×10²¹ cm⁻³. Such a drain region is formed, for example, by ion-implanting impurities having the same conductivity type as that of the substrate 25 into the lower surface of the substrate 25.

In addition, the configuration of the MOSFET is not limited to the example illustrated in FIG. 9 and may be any configuration. For example, in FIG. 9, the gate electrode 14 and the FP electrode 13 are provided in the identical insulating region 47. The present invention is not limited thereto, and the gate electrode 14 and the FP electrode 13 may be provided in insulating regions different from each other. Alternatively, the semiconductor device 1C may have a planar gate structure in which the gate electrode 14 and the insulating region are provided on the upper surface 2a of the semiconductor layer 2. Alternatively, the gate electrode 14 may also be provided inside the insulating regions 41 to 46 in the termination region.

According to the present embodiment, the contact portions 31 to 37 and the insulating regions 41 to 46 can be incorporated in a MOSFET or the like. As a result, in the MOSFET or the like, the qualities of the epitaxial growth layers 21 to 23 can be easily inspected. That is, it is possible to facilitate quality control (actual product QC) in an actual product. Note that, in the present embodiment, the configuration in which the semiconductor device 1 according to the first embodiment is incorporated in a MOSFET is described. The present invention is not limited thereto, and the semiconductor device 1B according to the second embodiment can be incorporated in a MOSFET.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

### Supplementary Note 1

A semiconductor wafer including:
a first semiconductor region in which an impurity concentration of the first or second conductivity type decreases from a lower surface toward an upper surface along a first direction that is a thickness direction;
a first insulating region that is provided from the upper surface of the first semiconductor region toward the lower surface of the first semiconductor region, of which a lower end is positioned at a height at which the impurity concentration of the first semiconductor region is a first concentration, and that extends in a second direction orthogonal to the first direction;
a second insulating region that is provided from the upper surface of the first semiconductor region toward the lower surface of the first semiconductor region, of which the lower end is positioned at a height at which the impurity concentration of the first semiconductor region is a second concentration lower than the first concentration, and that extends in the second direction;
first and second high-concentration layers that are provided on an upper surface of the first semiconductor region and that sandwich the first insulating region in a third direction orthogonal to the first direction and the second direction;
third and fourth high-concentration layers that are provided on the upper surface of the first semiconductor region and that sandwich the second insulating region in the third direction;
a first contact pair that includes a first contact portion electrically connected to the first high-concentration layer and a second contact portion electrically connected to the second high-concentration layer; and
a second contact pair that includes a third contact portion electrically connected to the third high-concentration layer and a fourth contact portion electrically connected to the fourth high-concentration layer.

### Supplementary Note 2

An inspection method for measuring a quality of a semiconductor region, the inspection method including:
preparing a semiconductor device including a first semiconductor region in which an impurity concentration of the first or second conductivity type decreases from a lower surface toward an upper surface along a first direction that is a thickness direction; a first insulating region that is provided from the upper surface of the first semiconductor region toward the lower surface of the first semiconductor region, of which a lower end is positioned at a height at which the impurity concentration of the first semiconductor region is a first concentration, and that extends in a second direction orthogonal to the first direction; a second insulating region that is provided from the upper surface of the first semiconductor region toward the lower surface of the first semiconductor region, of which the lower end is positioned at a height at which the impurity concentration of the first semiconductor region is a second concentration lower than the first concentration, and that extends in the second direction; first and second high-concentration layers that are provided on the upper surface of the first semiconductor region and that sandwich the first insulating region in a third direction orthogonal to the first direction and the second direction; third and fourth high-concentration layers that are provided on the upper surface of the first semiconductor region and that sandwich the second insulating region in the third direction; a first contact pair that includes a first contact portion electrically connected to the first high-concentration layer and a second contact portion electrically connected to the second high-concentration layer; and a second contact pair that includes a third contact portion electrically connected to the third high-concentration layer and a fourth contact portion electrically connected to the fourth high-concentration layer, and
measuring a first resistance value between the first and second contact portions and a second resistance value between the third and fourth contact portions.

What is claimed is:

1. A semiconductor device comprising:
a first semiconductor region in which an impurity concentration of a first or second conductivity type decreases from a lower surface toward an upper surface along a first direction that is a thickness direction;
a first insulating region that is provided from the upper surface of the first semiconductor region toward the lower surface of the first semiconductor region, wherein a lower end of the first insulating region is positioned at a height at which the impurity concentration of the first semiconductor region is a first concentration, and the first insulating region extends in a second direction orthogonal to the first direction;
a second insulating region that is provided from the upper surface of the first semiconductor region toward the lower surface of the first semiconductor region, wherein a lower end of the second insulating region is positioned at a height at which the impurity concentration of the first semiconductor region is a second concentration lower than the first concentration, and the second insulating region extends in the second direction;
first and second high-concentration layers that are provided on the upper surface of the first semiconductor region and that sandwich the first insulating region in a third direction orthogonal to the first direction and the second direction;
third and fourth high-concentration layers that are provided on the upper surface of the first semiconductor region and that sandwich the second insulating region in the third direction;
a first contact pair that includes a first contact portion electrically connected to the first high-concentration layer and a second contact portion electrically connected to the second high-concentration layer; and
a second contact pair that includes a third contact portion electrically connected to the third high-concentration layer and a fourth contact portion electrically connected to the fourth high-concentration layer.

2. The semiconductor device according to claim 1, wherein the first semiconductor region includes an epitaxial growth layer.

3. The semiconductor device according to claim 2, further comprising:
a sixth insulating region that is sandwiched between a bottom portion of the first insulating region and the first semiconductor region; and
a seventh insulating region that is sandwiched between a bottom portion of the second insulating region and the first semiconductor region.

4. The semiconductor device according to claim 2, further comprising:
an eighth insulating region that is provided from the upper surface of the first semiconductor region toward the lower surface of the first semiconductor region, wherein the eighth insulating region is adjacent to the first insulating region in the third direction, a lower end of the eighth insulating region is positioned at the same height as the first insulating region, the eighth insulating region extends in the second direction, and the eighth insulating region has the same width as the first insulating region;
a ninth insulating region that is provided from the upper surface of the first semiconductor region toward the lower surface of the first semiconductor region, wherein the ninth insulating region is adjacent to the second insulating region in the third direction, a lower end of the ninth insulating region is positioned at the same height as the second insulating region, the ninth insulating region extends in the second direction, and the ninth insulating region has the same width as the second insulating region;
eleventh and twelfth high-concentration layers that are provided on the upper surface of the first semiconductor region and that sandwich the eighth insulating region in the third direction;
thirteenth and fourteenth high-concentration layers that are provided on the upper surface of the first semiconductor region and that sandwich the ninth insulating region in the third direction;
a sixth contact pair that includes an eleventh contact portion electrically connected to the eleventh high-concentration layer and a twelfth contact portion electrically connected to the twelfth high-concentration layer; and
a seventh contact pair that includes a thirteenth contact portion electrically connected to the thirteenth high-concentration layer and a fourteenth contact portion electrically connected to the fourteenth high-concentration layer.

5. The semiconductor device according to claim 2,
wherein the first semiconductor region includes
a first epitaxial growth layer of which the impurity concentration is the first concentration;
a second epitaxial growth layer of which the impurity concentration is the second concentration and that is positioned on the first epitaxial growth layer; and
a third epitaxial growth layer of which the impurity concentration is a third concentration lower than the second concentration and that is positioned on the second epitaxial growth layer.

6. The semiconductor device according to claim 4, further comprising:
a sixth insulating region that is sandwiched between a bottom portion of the first insulating region and the first semiconductor region; and
a seventh insulating region that is sandwiched between a bottom portion of the second insulating region and the first semiconductor region.

7. The semiconductor device according to claim 1, further comprising:
a third insulating region that is provided from the upper surface of the first semiconductor region toward the lower surface of the first semiconductor region, wherein a lower end of the third insulating region is positioned at the same height as the first insulating region, the third insulating region extends in the second direction, and the third insulating region has a width different from that of the first insulating region;
a fourth insulating region that is provided from the upper surface of the first semiconductor region toward the lower surface of the first semiconductor region, wherein a lower end of the fourth insulating region is positioned at the same height as the second insulating region, the fourth insulating region extends in the second direction, and the fourth insulating region has a width different from that of the second insulating region;
fifth and sixth high-concentration layers that are provided on the upper surface of the first semiconductor region and that sandwich the third insulating region in the third direction;
seventh and eighth high-concentration layers that are provided on the upper surface of the first semiconductor region and that sandwich the fourth insulating region in the third direction;
a third contact pair that includes a fifth contact portion electrically connected to the fifth high-concentration layer and a sixth contact portion electrically connected to the sixth high-concentration layer; and
a fourth contact pair that includes a seventh contact portion electrically connected to the seventh high-concentration layer and an eighth contact portion electrically connected to the eighth high-concentration layer.

8. The semiconductor device according to claim 7, further comprising:
a sixth insulating region that is sandwiched between a bottom portion of the first insulating region and the first semiconductor region; and
a seventh insulating region that is sandwiched between a bottom portion of the second insulating region and the first semiconductor region.

9. The semiconductor device according to claim 7, further comprising:
an eighth insulating region that is provided from the upper surface of the first semiconductor region toward the lower surface of the first semiconductor region, wherein the eighth insulating region is adjacent to the first insulating region in the third direction, a lower end of the eighth insulating region is positioned at the same height as the first insulating region, the eighth insulating region extends in the second direction, and the eighth insulating region has the same width as the first insulating region;
a ninth insulating region that is provided from the upper surface of the first semiconductor region toward the lower surface of the first semiconductor region, wherein the ninth insulating region is adjacent to the second insulating region in the third direction, a lower end of the ninth insulating region is positioned at the same height as the second insulating region, the ninth insulating region extends in the second direction, and the ninth insulating region has the same width as the second insulating region;
eleventh and twelfth high-concentration layers that are provided on the upper surface of the first semiconductor region and that sandwich the eighth insulating region in the third direction;
thirteenth and fourteenth high-concentration layers that are provided on the upper surface of the first semiconductor region and that sandwich the ninth insulating region in the third direction;
a sixth contact pair that includes an eleventh contact portion electrically connected to the eleventh high-concentration layer and a twelfth contact portion electrically connected to the twelfth high-concentration layer; and
a seventh contact pair that includes a thirteenth contact portion electrically connected to the thirteenth high-concentration layer and a fourteenth contact portion electrically connected to the fourteenth high-concentration layer.

10. The semiconductor device according to claim 1, further comprising:
a fifth insulating region that is provided from the upper surface of the first semiconductor region toward the lower surface of the first semiconductor region, wherein a lower end of the fifth insulating region is positioned at a height at which the impurity concentration in the first semiconductor region is a concentration higher than the first concentration, and the fifth insulating region extends in the second direction;
ninth and tenth high-concentration layers that are provided on the upper surface of the first semiconductor region and that sandwich the fifth insulating region in the third direction; and
a fifth contact pair that includes a ninth contact portion electrically connected to the ninth high-concentration layer and a tenth contact portion electrically connected to the tenth high-concentration layer.

11. The semiconductor device according to claim 10, further comprising:
a sixth insulating region that is sandwiched between a bottom portion of the first insulating region and the first semiconductor region; and
a seventh insulating region that is sandwiched between a bottom portion of the second insulating region and the first semiconductor region.

12. The semiconductor device according to claim 10, further comprising:
an eighth insulating region that is provided from the upper surface of the first semiconductor region toward the lower surface of the first semiconductor region, wherein the eighth insulating region is adjacent to the first insulating region in the third direction, a lower end of the eighth insulating region is positioned at the same height as the first insulating region, the eighth insulating region extends in the second direction, and the eighth insulating region has the same width as the first insulating region;
a ninth insulating region that is provided from the upper surface of the first semiconductor region toward the lower surface of the first semiconductor region, wherein the ninth insulating region is adjacent to the second insulating region in the third direction, a lower end of the ninth insulating region is positioned at the same height as the second insulating region, the ninth insulating region extends in the second direction, and the ninth insulating region has the same width as the second insulating region;
eleventh and twelfth high-concentration layers that are provided on the upper surface of the first semiconductor region and that sandwich the eighth insulating region in the third direction;
thirteenth and fourteenth high-concentration layers that are provided on the upper surface of the first semiconductor region and that sandwich the ninth insulating region in the third direction;
a sixth contact pair that includes an eleventh contact portion electrically connected to the eleventh high-concentration layer and a twelfth contact portion electrically connected to the twelfth high-concentration layer; and
a seventh contact pair that includes a thirteenth contact portion electrically connected to the thirteenth high-concentration layer and a fourteenth contact portion electrically connected to the fourteenth high-concentration layer.

13. The semiconductor device according to claim 1, further comprising:
a sixth insulating region that is sandwiched between a bottom portion of the first insulating region and the first semiconductor region; and
a seventh insulating region that is sandwiched between a bottom portion of the second insulating region and the first semiconductor region.

14. The semiconductor device according to claim 13, further comprising:
an eighth insulating region that is provided from the upper surface of the first semiconductor region toward the lower surface of the first semiconductor region, wherein the eighth insulating region is adjacent to the first insulating region in the third direction, a lower end of the eighth insulating region is positioned at the same height as the first insulating region, the eighth insulating region extends in the second direction, and the eighth insulating region has the same width as the first insulating region;
a ninth insulating region that is provided from the upper surface of the first semiconductor region toward the lower surface of the first semiconductor region, wherein the ninth insulating region is adjacent to the second insulating region in the third direction, a lower end of the ninth insulating region is positioned at the same height as the second insulating region, the ninth insulating region extends in the second direction, and the ninth insulating region has the same width as the second insulating region;
eleventh and twelfth high-concentration layers that are provided on the upper surface of the first semiconductor region and that sandwich the eighth insulating region in the third direction;
thirteenth and fourteenth high-concentration layers that are provided on the upper surface of the first semiconductor region and that sandwich the ninth insulating region in the third direction;
a sixth contact pair that includes an eleventh contact portion electrically connected to the eleventh high-concentration layer and a twelfth contact portion electrically connected to the twelfth high-concentration layer; and
a seventh contact pair that includes a thirteenth contact portion electrically connected to the thirteenth high-concentration layer and a fourteenth contact portion electrically connected to the fourteenth high-concentration layer.

15. The semiconductor device according to claim 1, further comprising:
an eighth insulating region that is provided from the upper surface of the first semiconductor region toward the lower surface of the first semiconductor region, wherein the eighth insulating region is adjacent to the first insulating region in the third direction, a lower end of the eighth insulating region is positioned at the same height as the first insulating region, the eighth insulating region extends in the second direction, and the eighth insulating region has the same width as the first insulating region;
a ninth insulating region that is provided from the upper surface of the first semiconductor region toward the lower surface of the first semiconductor region, wherein the ninth insulating region is adjacent to the second insulating region in the third direction, a lower end of the ninth insulating region is positioned at the same height as the second insulating region, the ninth insulating region extends in the second direction, and the ninth insulating region has the same width as the second insulating region;
eleventh and twelfth high-concentration layers that are provided on the upper surface of the first semiconductor region and that sandwich the eighth insulating region in the third direction;
thirteenth and fourteenth high-concentration layers that are provided on the upper surface of the first semiconductor region and that sandwich the ninth insulating region in the third direction;
a sixth contact pair that includes an eleventh contact portion electrically connected to the eleventh high-concentration layer and a twelfth contact portion electrically connected to the twelfth high-concentration layer; and
a seventh contact pair that includes a thirteenth contact portion electrically connected to the thirteenth high-concentration layer and a fourteenth contact portion electrically connected to the fourteenth high-concentration layer.

16. A method for manufacturing a semiconductor device, the method comprising:
preparing a substrate;
forming, on the substrate, a first semiconductor region that includes first to third epitaxial growth layers, wherein an impurity concentration of a first or second conductivity type of the first semiconductor region decreases along a first direction that is a thickness direction; wherein the first semiconductor region is formed by
forming, on the substrate, the first epitaxial growth layer in which the impurity concentration is a first concentration;
forming, on the first epitaxial growth layer, the second epitaxial growth layer in which the impurity concentration is a second concentration lower than the first concentration; and
forming, on the second epitaxial growth layer, the third epitaxial growth layer of which the impurity concentration is a third concentration lower than the second concentration;
forming a first trench to a first height from an upper surface of the first semiconductor region toward a lower surface of the first semiconductor region, and forming a second trench to a second height from the upper surface of the first semiconductor region toward the lower surface of the first semiconductor region, wherein the first height is a height at which the impurity concentration is the first concentration, and the second height is a height at which the impurity concentration is the second concentration;
forming a first insulating region in the first trench and forming a second insulating region in the second trench;
forming first and second high-concentration layers that sandwich the first insulating region in a third direction orthogonal to the first direction and the second direction and third and fourth high-concentration layers that sandwich the second insulating region in the third direction, on the upper surface of the first semiconductor region; and
forming first and second contact portions electrically connected to the first and second high-concentration layers and third and fourth contact portions electrically connected to the third and fourth high-concentration layers.

17. The method for manufacturing a semiconductor device according to claim 16,
wherein the forming of the first semiconductor region includes forming a first stopper film on the substrate before the first epitaxial growth layer is formed,
forming a second stopper film on the first epitaxial growth layer after the first epitaxial growth layer is formed, and before the second epitaxial growth layer is formed, and
forming a third stopper film on the second epitaxial growth layer after the second epitaxial growth layer is formed, and before the third epitaxial growth layer is formed,
wherein the first trench is formed by removing the first semiconductor region in a portion above the second stopper film, and
the second trench is formed by removing the first semiconductor region in a portion above the third stopper film.

18. A semiconductor device comprising:
a first semiconductor region in which an impurity concentration of a first or second conductivity type decreases from a lower surface toward an upper surface along a first direction that is a thickness direction;
a first insulating region that is provided from the upper surface of the first semiconductor region toward the lower surface of the first semiconductor region, wherein a lower end of the first insulating region is positioned at a height at which the impurity concentration of the first semiconductor region is a first concentration, and the first insulating region extends in a second direction orthogonal to the first direction;
a second insulating region that is provided from the upper surface of the first semiconductor region toward the lower surface of the first semiconductor region, wherein a lower end of the second insulating region is positioned at the same height as that of the first insulating region, and the second insulating region extends in the second direction, and the second insulating region has a width different from that of the first insulating region;
first and second high-concentration layers that are provided on the upper surface of the first semiconductor region and that sandwich the first insulating region in a third direction orthogonal to the first direction and the second direction;
third and fourth high-concentration layers that are provided on the upper surface of the first semiconductor region and that sandwich the second insulating region in the third direction;
a first contact pair that includes a first contact portion electrically connected to the first high-concentration layer and a second contact portion electrically connected to the second high-concentration layer; and
a second contact pair that includes a third contact portion electrically connected to the third high-concentration layer and a fourth contact portion electrically connected to the fourth high-concentration layer.
